(19) United States
(12) Patent Application Publication
(10) Pub. No.: US 2011/0036398 A1
(43) Pub. Date: Feb. 17, 2011

(54) METHOD FOR MANUFACTURING A SEMICONDUCTOR COMPONENT

(75) Inventors: Bernd Bitnar, Freiberg (DE); Holger Neuhaus, Freiberg (DE)

Correspondence Address: VIERING, JENTSCHURA & PARTNER, 3770 HIGHLAND AVE., SUITE 203, MANHATTAN BEACH, CA, 90266, US

(73) Assignee: SOLARWORLD INNOVATIONS GMBH, Freiberg (DE)

(21) Appl. No.: 12/839,434

(22) Filed: Jul. 20, 2010

(30) Foreign Application Priority Data
Aug. 12, 2009 (DE) 10 2009 037 217.2

(51) Int. Cl. H01L 31/0224; H01L 31/18

(52) U.S. Cl. 136/256; 438/98; 257/E31.124

(57) ABSTRACT

An emitter wrap-through solar cell may include a semiconductor substrate having a first side, and a second side opposite the first side, contact structures having at least one emitter contact, and at least one base contact, wherein both the at least one emitter contact and the at least one base contact are arranged on the second side of the semiconductor substrate, and the contact structures have a metallization having nickel silicide.

### CROSS-REFERENCE TO RELATED APPLICATION

This application claims priority to German Patent Application Serial No. 10 2009 037 217.2, which was filed Aug. 12, 2009, and is incorporated herein by reference in its entirety.

### TECHNICAL FIELD

Various embodiments relate to a method for manufacturing a semiconductor component. Various embodiments furthermore relate to an emitter wrap-through (EWT) solar cell.

### BACKGROUND

In the case of an emitter wrap-through (EWT) solar cell, the emitter contact is led through holes in a wafer onto the rear side thereof. Consequently, the contacts for both poles, the base contact and the emitter contact, are then situated on the rear side of the solar cell. During the manufacturing of the holes in the wafer, the surface thereof is usually damaged, and so the damage has to be removed in a subsequent process step. A further problem consists in the fact that the passivation of those regions of the rear side which are not contact-connected is often not ensured to a sufficient extent. Finally, the production of EWT solar cells is very complicated and therefore expensive.

### SUMMARY OF THE INVENTION

In various embodiments, an emitter wrap-through solar cell may include a semiconductor substrate having a first side, and a second side opposite the first side, contact structures having at least one emitter contact, and at least one base contact, wherein both the at least one emitter contact and the at least one base contact are arranged on the second side of the semiconductor substrate, and the contact structures have a metallization having nickel silicide.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic illustration of a semiconductor component in different stages of a method in accordance with a first embodiment;

FIG. 2 shows a schematic illustration of a semiconductor component in different stages of a method in accordance with a second embodiment;

FIG. 3 shows a schematic illustration of a semiconductor component in different stages of a method in accordance with a third embodiment; and

FIG. 4 shows a schematic illustration of a semiconductor component in different stages of a method in accordance with a fourth embodiment.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various embodiments improve a method for producing a semiconductor component. Various embodiments furthermore provide an improved EWT solar cell.

Various embodiments provide a liquid jet-guided laser for introducing the holes into the semiconductor substrate for leading through the emitter contacts onto the rear side of said substrate, and producing the contact structures on the rear side of the semiconductor substrate includes applying nickel to the latter and subsequent diffusion of the nickel into the semiconductor substrate.

As a result, EWT solar cells having a high efficiency may be produced in a simple manner. The surface of the semiconductor substrates is not damaged by the liquid jet-guided laser method. Manufacturing the contact structures by means of applying nickel to the semiconductor substrate and subsequent diffusion of the nickel into said substrate leads to a particularly good electrical contact between the contact structures and the semiconductor substrate and considerably simplifies the production of the contact structures.

In various embodiments, the laser method may also be used for patterning the passivation layer on the rear side of the semiconductor substrate. By means of the laser method, openings can be introduced into the passivation layer in a simple manner. The holes in the semiconductor substrate and the openings for the contact structures can thus be produced in a single method step. The method is simplified even further as a result.

In various embodiments, the semiconductor substrate may be provided with a doping during the process of introducing the holes and/or the openings in the regions respectively adjoining the latter, by means of the liquid jet of the laser. The patterning of the contact structures and the doping thereof can thus be effected in a single process step. In this case, the semiconductor substrate can be provided with different dopings in the region of the emitter contacts and in the region of the base contacts in the same process step.

Applying the nickel to the semiconductor substrate by means of a sputtering method, a vapor deposition method or a chemical deposition is particularly simple to carry out and monitor.

A metallic thickening of the contact structures may lead to a reduction of the electrical resistance thereof and, as a result, to an increased efficiency.

The thickening of the contact structures can be regulated in a particularly simple manner by means of an electrodeposition. In various embodiments, it is possible in this case for the base contacts and the emitter contacts to be provided with thickenings of different thicknesses, for example, independently of one another.

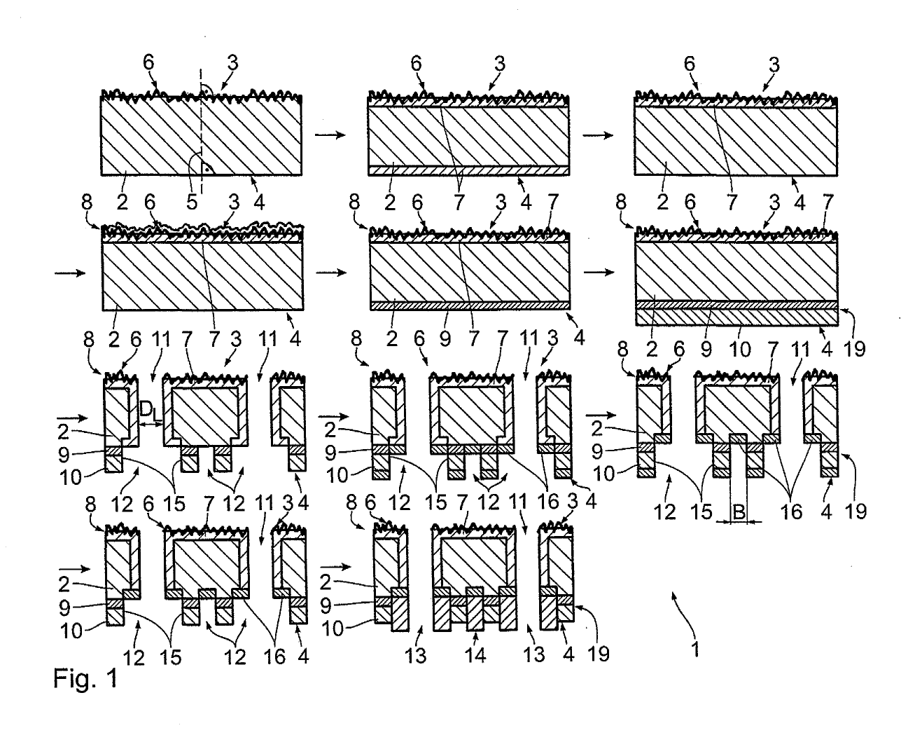

A first embodiment of the invention is described below with reference to FIG. 1.

As a starting point in the manufacturing of an emitter wrap-through (EWT) solar cell 1, use is made of a semiconductor substrate 2 embodied in planar fashion and having a first side, a second side opposite the latter, and a surface normal 5 perpendicular to the sides. In the finished EWT solar cell 1, the first side forms the front side 3 of the EWT solar cell 1, said front side facing the sun. In the finished EWT solar cell 1, the second side correspondingly forms the rear side 4 of the EWT solar cell 1, said rear side facing away from the sun.

In this case, the EWT solar cell 1 is a specific example of a semiconductor component. A wafer, e.g. a silicon wafer, serves as semiconductor substrate 2. However, alternative semiconductor substrates are likewise possible. The semiconductor substrate may be embodied in monocrystalline fashion. It can also be embodied in multicrystalline fashion. Ribbon-pulled silicon material produced by means of a ribbon growth on substrate (RGS) method, for example, can likewise be involved. In accordance with the embodiment described below, the semiconductor substrate 2 is p-doped.

In a first method step, the front side 3 may be provided with a texture 6. A chemical method, e.g. an etching method, is provided for texturing the front side 3. In this case, the rear side 4 can also simultaneously be provided with a texturing. As an alternative to this, a plasma texture method for texturing the front side 3 is also possible. For details of the texturing method, reference should be made to EP 0 944 114 A2 for example.

In the subsequent method step, the semiconductor substrate 2 is exposed to liquid or gaseous phosphorus oxychloride (POCl₃) in order to produce an n-doped surface layer 7—serving as an emitter—on the front side 3 and the rear side 4. The surface layer 7 has a sheet resistance in the range of 50 ohms to 200 ohms, e.g. in the range of 90 ohms to 110 ohms

In the subsequent method step, a phosphorus glass layer that has formed may be removed from the front and rear sides 3, 4. This can be done with the aid of dilute phosphoric acid. In addition, the surface layer 7 on the rear side 4 may be removed from the semiconductor substrate 2 by means of a phosphorus glass etching method. The rear side 4 of the semiconductor substrate 2 may subsequently be subjected to a single-side polishing etch. The texturing of the rear side 4 can be leveled in this case.

The front side 3 is then provided with a front side passivation layer 8. For this purpose, silicon nitride (SiN) may be deposited on the front side 3. A physical vapor deposition (PVD) or a chemical vapor deposition (CVD) may be provided for depositing the front side passivation layer 8. The front side passivation layer 8 is schematically illustrated explicitly as a separate layer on the texture 6 only in the fourth method step in FIG. 1. In the remaining figures, where it is present, it is merely indicated by the reference symbol 8.

In the subsequent method step, the semiconductor substrate 2 may be cleaned and the second side 4 is provided with an oxide layer 9 by means of a thermal oxidation. The oxide layer 9 may have a thickness in the direction of the surface normal 5 in the range from about 10 nm to about 20 nm.

In the subsequent method step, the oxide layer 9 on the rear side 4 of the semiconductor substrate 2 may be thickened. By way of example, the deposition of a silicon oxide (SiO) layer 10 onto the oxide layer 9 may be provided for this purpose. The oxide layer 9 thickened by the SiO layer 10 forms a passivation layer 19 on the rear side 4 of the semiconductor substrate 2.

The SiO deposition may be effected by means of physical vapor deposition (PVD) or chemical vapor deposition (CVD), e.g. plasma-enhanced chemical vapor deposition (PECVD). A sputtering method may also be provided instead of the PVD or CVD method for thickening the oxide layer 9.

Instead of the silicon oxide layer 10, the thermal oxide layer 9 may also be thickened by a layer composed of a silicon nitride, for example silicon oxynitride, amorphous silicon, silicon dioxide, aluminum nitride, silicon carbide or a stack composed of at least two layers of this type.

In the subsequent method step, holes 11 may be introduced into the semiconductor substrate 2. The holes 11 completely penetrate through the semiconductor substrate 2 with the passivation layer 19. A liquid jet-guided laser may be provided for introducing the holes 11 into the semiconductor substrate 2. In the case of said laser, the laser beam may be guided by means of total reflection at the liquid-air interface of a liquid jet in this liquid jet serving as a liquid, fiber-optic waveguide. By means of a liquid jet-guided laser of this type, holes 11 having a diameter D_{L} in the range from about 30 μm to about 100 μm are introduced into the semiconductor substrate 2 precisely and in a controlled fashion. In addition, the liquid jet may be provided with a dopant, which is driven into the semiconductor substrate 2 by the laser radiation. In other words, the semiconductor substrate 2 may be provided with a doping during the process of introducing the holes 11 simultaneously in the regions adjoining the holes 11 in a direction perpendicular to the surface normal 5. In accordance with the first embodiment, the doping of the holes 11 may be effected by means of a phosphoric acid jet laser method. The regions adjoining the holes 11 are thus provided with phosphorus doping, that is to say with an n-type doping. They therefore form an emitter structure. The production of the emitter structure in the holes 11 is therefore effected in the same method step as the drilling of the holes 11. An additional etching step is not necessary.

In addition, the passivation layer 19 on the rear side 4, e.g. the oxide layer 9, may be provided with openings 12 by means of the laser method. Through the openings 12, the second side 4 of the semiconductor substrate 2 is uncovered in regions. In various embodiments, the introduction of the openings 12 into the passivation layer may be effected in the same laser apparatus as the introduction of the holes 11 into the semiconductor substrate 2. It is possible, in various embodiments, to introduce the holes 11 into the semiconductor substrate 2 and the openings 12 into the passivation layer 19 in a single method step. It goes without saying that it is also possible to provide separate apparatuses for introducing the holes 11 and for introducing the openings 12.

A first portion of the openings 12 may overlap the holes 11 in the direction of the surface normal 5, while a second portion of the openings 12 is arranged without any overlap with the holes 11. In this case, the first portion of the openings 12 is formed non-contiguously with the second portion of the openings 12.

The first portion of the openings 12 has a width B in a direction perpendicular to the surface normal 5 in the range of 30 μm to 300 μm. In this case, the first portion of the openings 12 has, in at least one direction perpendicular to the surface normal 5, dimensions which are larger than the dimensions of the respective underlying holes 11 in order that a respective emitter contact 13 can be applied in the corresponding edge regions at the transition from a hole 11 to the opening 12.

The width of the second portion of the openings 12 may be in the range from about 30 μm to about 100 μm.

The openings 12 are laterally bounded by sidewalls 15. The sidewalls 15 may be embodied in steep fashion, that is to say that they form an angle in the range of 70° to 100° with the rear side 4 of the semiconductor substrate 2.

The semiconductor substrate 2 is provided, in the region of the first portion of the openings 12 which overlap the holes 11 at least in part, with a doping corresponding to that in the region of the holes 11. Emitter contacts 13 are formed in this first portion of the openings 12 in the subsequent method steps.

By contrast, base contacts 14 are subsequently formed in the region of the second portion of the openings 12. In this portion of the openings 12, the semiconductor substrate 2 may be provided with a p-type doping for forming base structures. For this purpose, provision may be made for using, for the purpose of introducing the openings 12 for the base contacts 14, an undoped water jet or a liquid jet having a dopant for a suitable base doping, for example boron or aluminum, for guiding the laser.

Consequently, the semiconductor substrate 2 may be provided with different dopings in the region of the first portion of the openings 12 for producing the emitter contacts 13 and in the region of the second portion of the openings 12 for producing the base contacts 14. The emitter contacts 13 and the base contacts 14 are part of the contact structures of the EWT solar cell 1.

One particular advantage of the method according to various embodiments may be that the introduction of the holes 11 for leading through the emitter contacts 13 from the front side 3 onto the rear side 4 of the semiconductor substrate 2 can be effected in the same method step, e.g. simultaneously with the introduction of the openings 12 for the emitter contacts 13 and the openings 12 for the base contacts 14 into the passivation layer on the rear side 4 of the semiconductor substrate 2.

The openings 12 may be embodied as linear trenches. In this case, the figures show a section perpendicular to the course of said trenches. In this embodiment, the openings 12 linearly interconnect a multiplicity of holes 11 forming emitter regions. They have a width B in a direction perpendicular to the surface normal 5 of at most 100 μm, e.g. of at most 50 μm, e.g. of at most 30 μm. They are bounded laterally by sidewalls 15. The sidewalls 15 may be embodied in steep fashion, that is to say that they form an angle in the range of 70° to 100° with the rear side 4 of the semiconductor substrate 2.

One variant of the embodiment provides for the openings 12 to be embodied in punctiform fashion. In this case, punctiform openings 12 may be understood to mean those having dimensions perpendicular to the surface normal 5 of at most 100 μm, e.g. of at most 50 μm, e.g. of at most 30 μm. It goes without saying that the openings 12 can also be embodied partly in punctiform fashion and partly in linear fashion.

The openings 12 for the emitter contacts 13 may have larger dimensions perpendicular to the surface normal 5 than the openings 12 for the base contacts 14. In various embodiments, the width B of the openings 12 for the emitter contacts 13 is at least twice as large as the width B of the openings 12 for the base contacts.

In the subsequent method steps, the emitter contacts 13 and the base contacts 14 are produced.

Both the emitter contacts 13 and the base contacts 14 are arranged at least in part, in various embodiments completely, on the rear side 4 of the semiconductor substrate 2.

Manufacturing the emitter contacts 13 and the base contacts 14 may include applying nickel to the second side 4 of the semiconductor substrate 2. The nickel may be applied to the semiconductor substrate 2 e.g. in the region of the openings 12. It is thus in direct contact with the semiconductor substrate 2. The nickel is applied to the second side 4 of the semiconductor substrate 2 by sputtering or vapor deposition after brief immersion of the semiconductor substrate 2 in hydrofluoric acid. A CVD method or a PVD method can be provided for applying the nickel. A chemical deposition of the nickel is likewise possible. The nickel may thus be applied to the second side 4 of the semiconductor substrate 2 over the whole area. The nickel layer has a thickness in the direction of the surface normal 5 in the range from about 20 nm to about 100 nm, e.g. in the range from about 30 nm to about 50 nm, e.g. in the range from about 40 nm to about 45 nm.

In the subsequent method step, a thermal method is provided for the diffusion of the nickel into the semiconductor substrate 2. For this purpose, the semiconductor substrate 2 with the nickel applied thereon may be heated. The temperature for the diffusion step may be in the range from about 200° C. to about 600° C., e.g. in the range from about 300° C. to about 500° C. In this case, the nickel diffuses into the semiconductor substrate 2. Nickel silicide (NiSi) may be formed during the diffusion of the nickel into the semiconductor substrate 2.

The nickel deposited in the openings 12, e.g. the nickel silicide (NiSi) that forms during the diffusion of said nickel in the region of the openings 12, forms conductor tracks 16.

In particular, a so-called “rapid thermal annealing” method can be provided for the diffusion of the nickel into the semiconductor substrate 2. In this case, the semiconductor substrate 2 is brought to a temperature of at least 300° C., e.g. of at least 500° C., e.g. of at least 700° C., for a time duration in the range from about one second to about 60 seconds, e.g. in the range from about 10 seconds to about 30 seconds.

After the formation of the nickel silicide in the region of the openings 12, the nickel on the passivation layer 19 may be removed. An etching step may be provided for this purpose. The etching of the nickel on the passivation layer 19 may be effected for example in nitric acid, e.g. dilute nitric acid. Instead of nitric acid, the etching of the nickel layer on the passivation layer 19 can be effected by a mixture of sulfuric acid and hydrogen peroxide, sulfuric acid and ozone, nitric acid and ozone, hydrochloric acid and ozone, or hydrochloric acid and hydrogen peroxide.

The nickel silicide of the conductor tracks 16 is not attacked during the etching step for removing the nickel on the passivation layer 19. The conductor tracks 16 thus remain intact.

In the subsequent method step, the conductor tracks 16 composed of nickel silicide are thickened. Their linear resistance is reduced as a result. The conductor tracks 16 composed of nickel silicide may be thickened by copper and/or nickel and/or silver or compounds of these metals or a stack of these metals or compounds. An electrolytic method may be provided for thickening the conductor tracks 16.

The finished EWT solar cell 1 thus may include the semiconductor substrate 2 with the emitter contacts 13 and the base contacts 14, wherein these contact structures have a metallization including nickel silicide. Both the emitter contacts 13 and the base contacts 14 are arranged on the rear side 4 of the EWT solar cell 1. The front side 3 of the EWT solar cell 1 may thus be free of contact structures. Therefore, it is not shaded by contact structures. The efficiency of the EWT solar cell 1 according to various embodiments may be increased as a result.

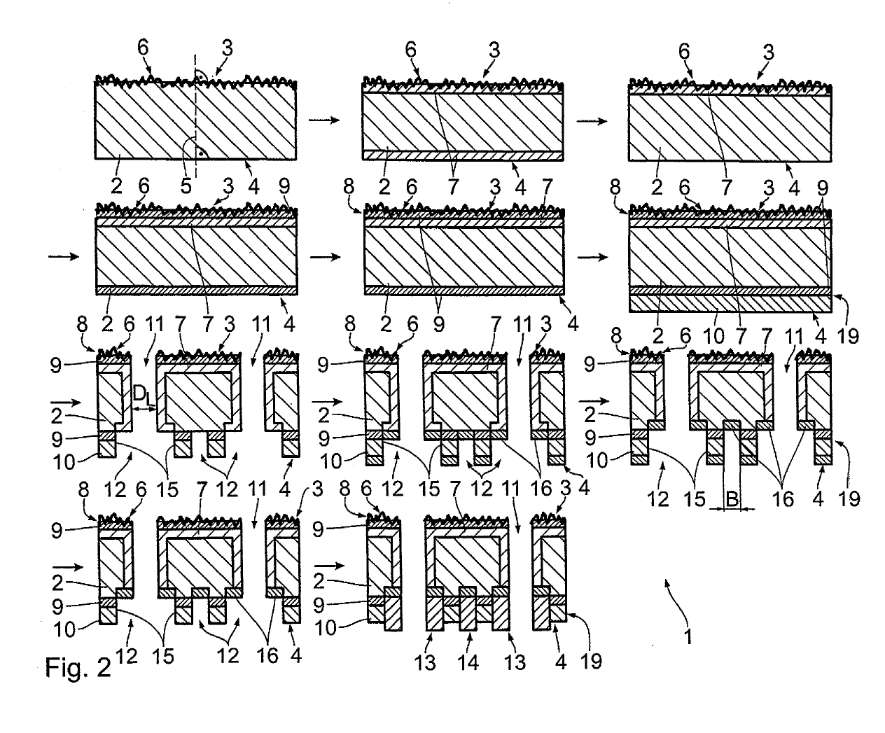

A second embodiment is described below with reference to FIG. 2. The second embodiment substantially corresponds to the first embodiment, to the description of which reference is hereby made. In contrast to the first embodiment, the cleaning of the semiconductor substrate 2 may be effected together with the rear side etch and/or the method step for removing the phosphorus glass layer. In the second embodiment, the thermal oxidation of the rear side 4 of the semiconductor substrate 2 may be effected before the deposition of the silicon nitride on the front side 3 of the semiconductor substrate 2. The cleaning step between the SiN deposition and the thermal oxidation may be omitted. Moreover, the passivation of the front side 3 may be improved further as a result. This embodiment is suitable, by way of example, for semiconductor substrates 2 whose emitter layer on the front side 3 has a sheet resistance of at least 80 ohms. Otherwise, the oxide layer grows significantly more thickly on the front side 3 than on the rear side 4.

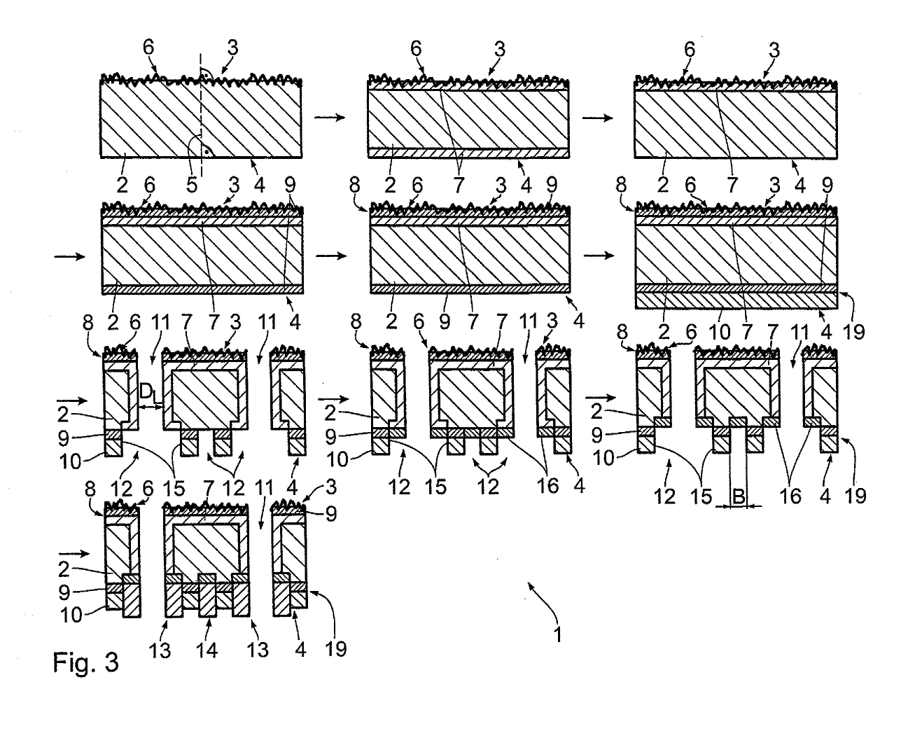

A third embodiment of the invention is described below with reference to FIG. 3. This embodiment substantially corresponds to the second embodiment, to the description of which reference is hereby made. In contrast to the second embodiment, the nickel is deposited during the production of the emitter and base contacts 13 and 14 by means of a chemical method. This has the advantage that the nickel is deposited selectively in the openings 12. A subsequent etching step can be omitted.

In a further variant of this embodiment, the heat treatment step for diffusion of nickel silicide may not be effected until after the electrolytic thickening of the chemically deposited nickel.

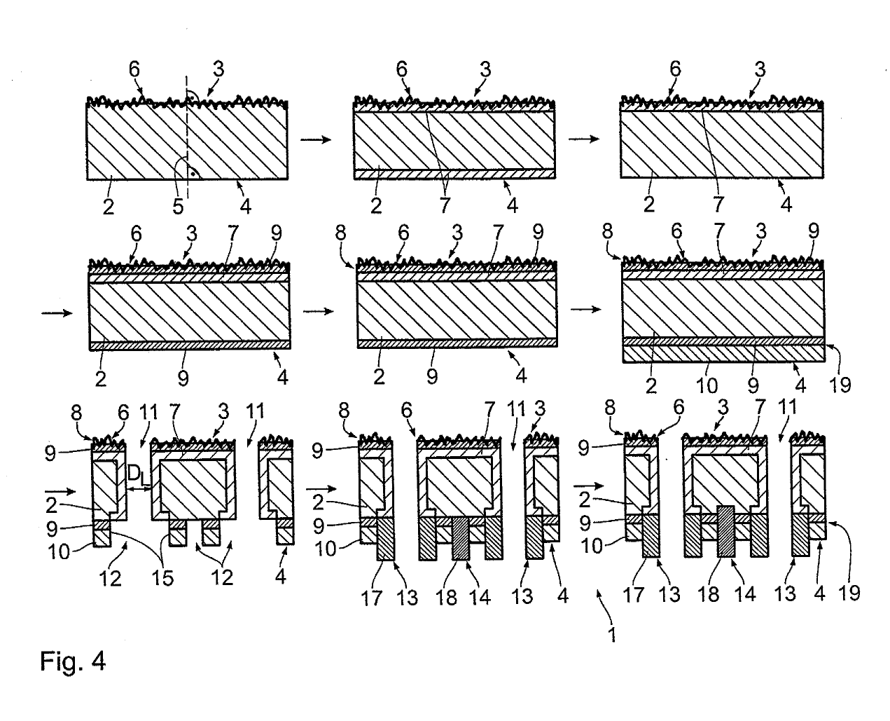

A fourth embodiment of the invention is described below with reference to FIG. 4. Up to the introduction of the holes 11 into the semiconductor substrate 2 and the openings 12 into the passivation layer on the rear side 4 of the semiconductor substrate 2, the fourth embodiment corresponds to the second embodiment, to the description of which reference is hereby made. In accordance with the embodiments described previously, in the fourth embodiment, after the production of the holes 11 and the openings 12, at least in the region of the openings 12 aligned with the holes 11, nickel may be deposited onto the rear side 4 of the semiconductor substrate 2. A sputtering method or a chemical method is once again provided for this purpose.

In contrast to the previous embodiments, in this embodiment, the metallization of the emitter and base contacts 13 and 14 may be produced by an extrusion printing method, e.g. a coextrusion printing method. By way of example, a silver paste 17 is used for the emitter contacts 13. It may be advantageously possible to apply the nickel in the region of the openings 12 aligned with the holes 11 likewise by means of the extrusion printing method, e.g. the coextrusion printing method. The prior deposition of nickel by means of an additional sputtering or chemical method can be omitted in this case. This case is illustrated in FIG. 4. In this variant, a layer stack composed of nickel and silver may advantageously be printed onto the semiconductor substrate 2. By way of example, an aluminum paste 18 is used for the base contacts 14. The aluminum paste 18 for producing the base contacts 14 may be provided with a glass frit. In this case, it is possible to dispense with introducing the second portion of the openings 12, that is to say of the openings 12 for the base contacts 14, or, to put it another way, of the openings 12 which are arranged without any overlap with the holes 11. After the extrusion step, an electrical contact of the pastes 17, 18 with the semiconductor substrate 2 may be produced in a so-called fast-firing method. The nickel silicide may also be formed in this case.

In order to achieve a greatest possible metal coverage of the rearside 4 of the semiconductor substrate 2, in a variant of the fourth embodiment, a third substance can be printed as a separating layer between the emitter and base contacts 13 and 14. Said separating layer prevents coalescence of the contacts 13, 14. The separating layer may be burned away during the fast-firing method. It serves exclusively for spatially separating the emitter and base contacts 13, 14 during the extrusion method.

In the coextrusion method, the pastes 17, 18 for the production of the emitter and base contacts 13, 14 and also, if appropriate, the separating layer are applied to the semiconductor substrate 2 in a single process step, in various embodiments simultaneously.

It goes without saying that an n-doped semiconductor substrate, e.g. an n-doped silicon wafer, can also serve as semiconductor substrate 2 in all of the embodiments described previously. In this case, the diffusion of phosphorus oxychloride for forming an emitter layer is replaced by diffusion of boron chloride (BCl₃). Correspondingly, the regions adjoining the holes 11 and the regions for the emitter contacts 13 on the rear side 4 of the semiconductor substrate 2 are provided with a p-type doping. Boron- or aluminum-containing solutions are suitable for this purpose. By contrast, the regions for the base contacts 14 are then provided with an n-type doping.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method for producing a semiconductor component, the method comprising:
providing a planar semiconductor substrate comprising
a first side,
a second side opposite the first side, and
a surface normal perpendicular to the sides,
applying a passivation layer to at least the second of the sides,
introducing holes into the semiconductor substrate by means of a liquid jet-guided laser, wherein the holes completely penetrate through the semiconductor substrate with the passivation layer,
producing contact structures in electrical contact with the semiconductor substrate, wherein the contact structures comprise at least one base contact and at least one emitter contact, wherein the contact structures are arranged at least in part on the second side of the semiconductor substrate and wherein producing the contact structures comprises applying nickel to the semiconductor substrate and subsequent diffusion of the nickel into the semiconductor substrate.

2. The method as claimed in claim 1,
wherein producing the contact structures comprises introducing openings into the passivation layer on the second side of the semiconductor substrate by means of a laser in order to uncover the second side of the semiconductor substrate in regions.

3. The method as claimed in claim 2,
wherein the holes and the openings are introduced by means of a single laser apparatus.

4. The method as claimed in claim 3,
wherein the holes and the openings are introduced by means of a single laser apparatus in a single method step.

5. The method as claimed in claim 1,
wherein the semiconductor substrate is provided with a doping during the process of introducing at least one of the holes and the openings in the regions respectively adjoining the latter, by means of the liquid jet of the laser.

6. The method as claimed in claim 2,
wherein a first portion of the openings for producing the at least one emitter contact overlaps the holes in the direction of the surface normal, while a second portion of the openings for producing the at least one base contact is arranged without any overlap with the holes, wherein the first portion of the openings is formed non-contiguously with the second portion of the openings.

7. The method as claimed in claim 6,
wherein the semiconductor substrate is provided, in the region of the first portion of the openings, with a doping corresponding to that in the region of the holes.

8. The method as claimed in claim 6,
wherein the semiconductor substrate is provided with different dopings in the region of the first portion of the openings for producing the at least one emitter contact and in the region of the second portion of the openings for producing the at least one base contact.

9. The method as claimed in claim 1,
wherein a method is provided for applying the nickel to the semiconductor substrate selected from a group consisting of: a sputtering method; a vapor deposition method; a chemical deposition; and an extrusion printing method.

10. The method as claimed in claim 1,
wherein a thermal method is provided for the diffusion of the nickel into the semiconductor substrate.

11. The method as claimed in claim 1,
wherein nickel silicide is formed during the diffusion of the nickel into the semiconductor substrate.

12. The method as claimed in claim 11,
wherein producing the contact structures comprises metallic thickening of the nickel silicide, wherein at least one of at least one layer of a material selected from a group consisting of are provided for the thickening process: copper; nickel; silver; aluminum; and compounds of these elements.

13. The method as claimed in claim 12,
wherein an electrodeposition is provided for thickening the contact structures.

14. The method as claimed in claim 13,
wherein producing the contact structures comprises an extrusion printing method.

15. The method as claimed in claim 14,
wherein producing the contact structures comprises a coextrusion printing method.

16. The method as claimed in claim 14,
wherein the contact structures of the at least one emitter contact and the contact structures of the at least one base contact are simultaneously applied to the semiconductor substrate, wherein a separating layer for preventing a coalescence of the same is extruded.

17. The method as claimed in claim 16,
wherein the separating layer for preventing a coalescence of the same is extruded between the contact structures of the at least one emitter contact and the at least one base contact.

18. An emitter wrap-through solar cell, comprising:
a semiconductor substrate comprising:
a first side, and
a second side opposite the first side,
contact structures comprising:
at least one emitter contact, and
at least one base contact,
wherein both the at least one emitter contact and the at least one base contact are arranged on the second side of the semiconductor substrate, and
the contact structures have a metallization comprising nickel silicide.
